(19) United States
(12) Patent Application Publication
(10) Pub. No.: US 2003/0129804 A1
(43) Pub. Date: Jul. 10, 2003

(54) Process for reducing dopant loss for semiconductor devices

(76) Inventors: Manoj Mehrotra, Plano, TX (US); Wayne A. Bather, Richardson, TX (US); Reji K. Koshy, Rowlett, TX (US); Amitabh Jain, Richardson, TX (US); Mark S. Rodder, University Park, TX (US); Rajesh B. Khamankar, Coppell, TX (US); Paul A. Tiner, Plano, TX (US); Rick L. Wise, Fairview, TX (US); Darin K. Wedel, Euless, TX (US)

Correspondence Address: TEXAS INSTRUMENTS INCORPORATED, P O BOX 655474, M/S 3999, DALLAS, TX, 75265

(21) Appl. No.: 10/146,457

(22) Filed: May 14, 2002

Related U.S. Application Data
(60) Provisional application No. 60/346,510, filed on Jan. 7, 2002.

(51) Int. Cl. H01L 21/336

(52) U.S. Cl. 438/303

(57) ABSTRACT

A method of forming a semiconductor device includes doping at least one region of an at least partially formed semiconductor device. The method further includes depositing at least one spacer layer outwardly from the at least one region of the at least partially formed semiconductor device. The at least one deposited spacer layer is formed in an environment that substantially minimizes dopant loss and deactivation in the at least one region of the at least partially formed semiconductor device.

### RELATED APPLICATIONS

This application claims the benefit under 35 U.S.C. §119(e) of U.S. Provisional Applicaton Serial No. 60/346,510, filed Jan. 7, 2002.

### TECHNICAL FIELD OF THE INVENTION

This invention relates generally to the field of semiconductor devices and, more specifically, to a method for depositing one or more dielectric spacer layers without significantly affecting dopant concentrations within the semiconductor device.

### OVERVIEW

Spacer layers used in semiconductor devices can protect portions of the semiconductor device during formation of doped regions. Conventional methods of forming the spacer layers often lead to dopant loss and deactivation of a doped semiconductor gate and/or doped drain extension areas of the semiconductor device. Dopant loss and deactivation can lead to an increase in the semiconductor device sheet resistance, a lower semiconductor device drive current, and a reduced gate to substrate capacitance.

### SUMMARY OF EXAMPLE EMBODIMENTS

The present invention provides an improved apparatus and method for minimizing dopant loss and deactivation in one or more doped regions of a semiconductor device. In accordance with the present invention, an apparatus and method for minimizing dopant loss and deactivation is provided that reduce or eliminate at least some of the shortcomings associated with prior approaches.

In a method embodiment, a method of forming a semiconductor device comprises doping at least one region of an at least partially formed semiconductor device. The method further comprises depositing at least one spacer layer outwardly from the at least one region of the at least partially formed semiconductor device. The at least one deposited spacer layer is formed in an environment that substantially minimizes dopant loss and deactivation in the at least one region of the at least partially formed semiconductor device.

In another method embodiment, a method of forming a semiconductor device comprises doping at least one region of an at least partially formed semiconductor device. The method further comprises depositing at least one spacer layer outwardly from the at least one region of the at least partially formed semiconductor device. The at least one spacer layer is deposited at an average rate of at least four (4) Angstroms per minute. In one particular embodiment, the at least one spacer layer comprises a dielectric material comprising at least seven (7) percent hydrogen and no more than fifty-one (51) percent nitrogen after depositing. The at least one spacer layer is deposited in an environment comprising a temperature of 500 to 650 degrees Celsius.

In one embodiment, a transistor formed using a method that comprises doping at least one region of an at least partially formed transistor. The method further comprises depositing at least one spacer layer outwardly from the at least one region of the at least partially formed transistor. In one particular embodiment, the at least one deposited spacer layer is formed in an environment that substantially minimizes dopant loss and deactivation in the at least one region of the at least partially formed transistor. The at least one deposited spacer layer is formed in the environment, while maintaining an average deposition rate for the at least one deposited spacer layer of at least four (4) Angstroms per minute.

Depending on the specific features implemented, particular embodiments of the present invention may exhibit some, none, or all of the following technical advantages. Various embodiments minimize dopant loss and deactivation in the gate and/or drain extension areas of the semiconductor device. Some embodiments may substantially improve semiconductor device conductivity and improve the gate to substrate capacitance of the semiconductor device.

Other technical advantages will be readily apparent to one skilled in the art from the following figures, descriptions and claims. Moreover, while specific advantages have been enumerated above, various embodiments may include all, some or none of the enumerated advantages.

### BRIEF DESCRIPTION OF THE DRAWINGS

For a more complete understanding of the present invention, and for further features and advantages thereof, reference is now made to the following description taken in conjunction with the accompanying drawings, in which:

FIGS. 1A through 1F are cross sectional views showing one example of a method of forming a portion of semiconductor device;

FIG. 2 is a graph comparing example temperatures and deposition rates of a spacer layer in various environments;

FIG. 3 is a graph comparing the resistance of example semiconductor devices where each spacer layer is formed in either a BTBAS environment or a DCS environment; and

FIG. 4 is a graph comparing the substrate to gate capacitance of example semiconductor devices where each spacer layer is formed in either a BTBAS environment or a DCS environment.

### DETAILED DESCRIPTION OF EXAMPLE EMBODIMENTS

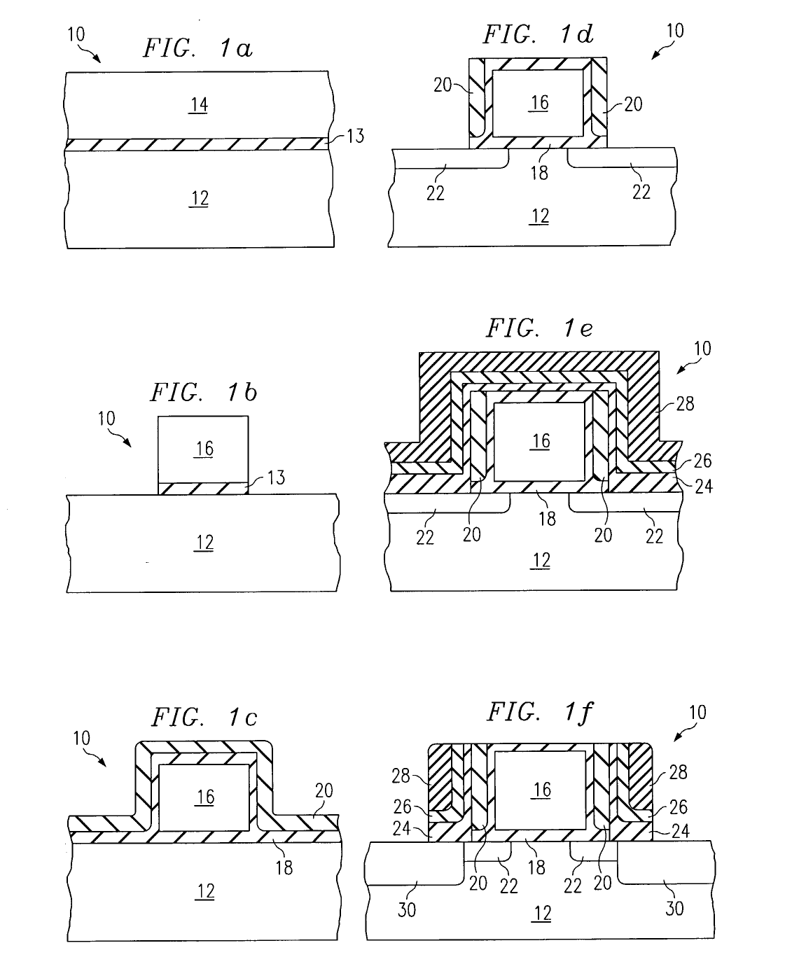

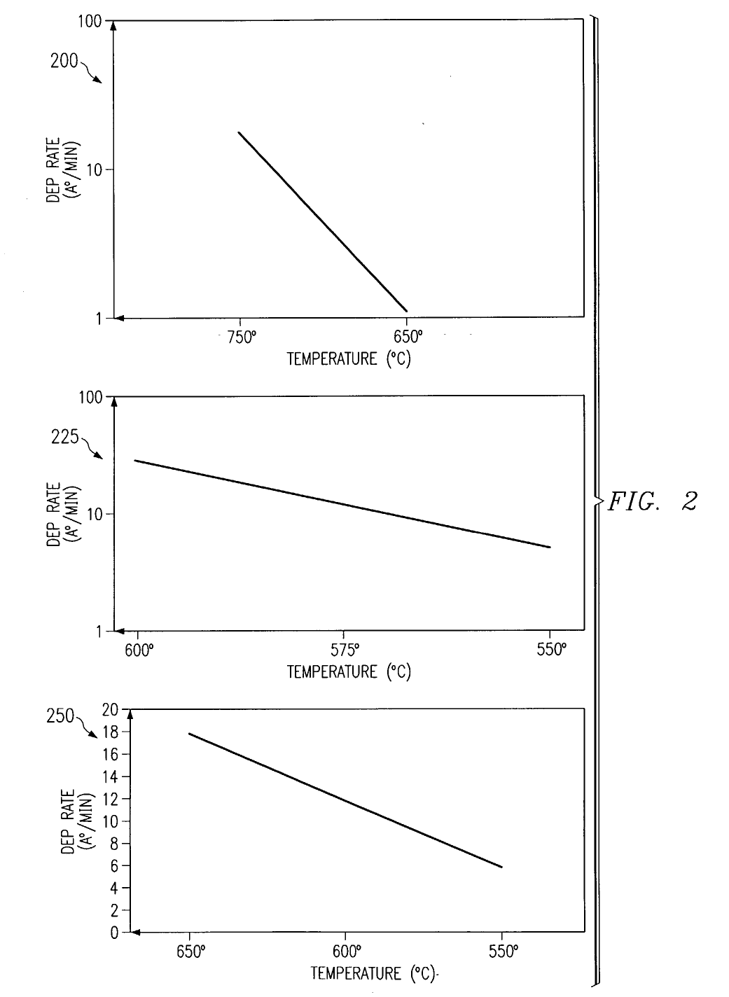

FIGS. 1A through 1F are cross-sectional views showing one example of a method of forming a portion of semiconductor device 10. Semiconductor device 10 may be used as a basis for forming any of a variety of semi-conductor devices, such as a bipolar junction transistor, a NMOS transistor, a PMOS transistor, a CMOS transistor, a diode, a capacitor, or other semiconductor based devices. Particular examples and dimensions specified throughout this document are intended for exemplary purposes only, and are not intended to limit the scope of the present disclosure. Moreover, the illustration in FIGS. 1A through 1F are not intended to be to scale.

FIG. 1A shows a cross sectional view of semiconductor device 10 after formation of a gate dielectric layer 13 disposed outwardly from a semiconductor substrate 12 and after formation of a gate electrode layer 14 outwardly from gate dielectric layer 13. Although gate dielectric layer 13 and gate electrode layer 14 are shown as being formed without interstitial layers between them, such interstitial layers could alternatively be formed without departing from the scope of the present disclosure. Semiconductor substrate 12 may comprise any suitable material used in semiconductor chip fabrication, such as silicon or germanium. Gate dielectric layer 13 may comprise, for example, oxide, silicon dioxide, or oxi-nitride.

Forming gate dielectric layer 13 may be affected through any of a variety of processes. For example, gate dielectric layer 13 can be formed by growing an oxide. In this particular example, gate dielectric layer 13 comprises a grown oxide with a thickness of approximately 15 to 25 angstroms. Using a grown oxide as gate dielectric layer 13 is advantageous in providing a mechanism for removing surface irregularities in semiconductor substrate 12. For example, as oxide is grown on the surface of substrate 12, a portion of substrate 12 is consumed, including at least some of the surface irregularities.

At some point, the active areas of semiconductor device 10 can be formed. Active areas of semiconductor device 10 may be formed, for example, by doping those areas to adjust the threshold voltage Vₜ of semiconductor device 10. This doping may comprise, for example, low energy ion implantation through gate dielectric layer 13. In another embodiment (not explicitly shown), a sacrificial dielectric layer may be disposed prior to formation of gate dielectric layer 13. In that case, the active regions of semiconductor device 10 are doped by implantation through the sacrificial dielectric layer. Then, the sacrificial dielectric layer is removed, and gate dielectric layer 13 is formed.

Gate electrode layer 14 may comprise, for example, amorphous silicon or polysilicon. In this example, gate electrode layer 14 comprises polysilicon. Forming gate electrode layer 14 may be affected, for example, by depositing polysilicon.

In some embodiments, after forming gate electrode layer 14, gate electrode layer 14 may be doped to achieve a relatively high gate capacitance. Implantation of gate electrode layer 14 depends at least in part on the active area formed within semiconductor substrate 12. In one particular embodiment, the active area formed within substrate 12 comprises an n-type well. In that embodiment, gate electrode layer 14 comprises an n-type implant.

FIG. 1B shows a cross sectional view of semiconductor device 10 after formation of a semiconductor gate 16 outwardly from substrate 12. Forming semiconductor gate 16 may be affected through any of a variety of processes. For example, semiconductor gate 16 can be formed by patterning and etching gate electrode layer 14 and gate dielectric layer 13 using photo resist mask and etch techniques.

FIG. 1C shows a cross sectional view of semiconductor device 10 after formation of a first screen dielectric layer 18 outwardly from semiconductor substrate 12 and after formation of a first spacer layer 20 outwardly from first screen dielectric layer 18. Although first screen dielectric layer 18 and first spacer layer 20 are shown as being formed without interstitial layers between them, such interstitial could alternatively be formed without departing from the scope of the present disclosure. First screen dielectric layer 18 may comprise, for example, oxide, oxi-nitride, or silicon oxide. In this particular embodiment, first screen dielectric layer 18 comprises oxide with a thickness of approximately 1-100 angstroms.

Forming first screen dielectric layer 18 may be affected through any of a variety of processes. For example, first screen dielectric layer 18 can be formed by growing an oxide. Using a grown oxide as first screen dielectric layer 18 is advantageous in providing a mechanism for removing surface irregularities in substrate 12 and semiconductor gate 16 created during the formation of gate 16.

First spacer layer 20 may comprise any dielectric material, such as, for example, nitride, silicon nitride, oxide, oxi-nitride, or silicon oxide. In some embodiments, first spacer layer 20 may comprise a dielectric material comprising at least seven (7) percent hydrogen and no more than fifty-one (51) percent nitrogen. In other embodiments, first spacer layer 20 may comprise a dielectric material comprising at least fourteen (14) percent hydrogen and no more than forty-two (42) percent nitrogen. The hydrogen concentration within spacer layer 20 denotes that spacer layer 20 was formed in an environment that comprises hydrogen. The higher the concentration of hydrogen in spacer layer 20 the greater the hydrogen concentration in the environment.

In the illustrated embodiment, first spacer layer 18 comprises a dielectric material that is selectively etchable from first spacer layer 20. That is, each of first screen dielectric layer 18 and first spacer layer 20 can be removed using an etching that does not significantly affect the other. For example, first screen dielectric layer 18 may comprise a layer of oxide while first spacer layer 20 may comprise, for example, nitride. In this example, first spacer layer 20 comprises nitride with a thickness of approximately 1-100 angstroms. Forming first spacer layer 20 may be affected, for example, by depositing a dielectric material outwardly from first screen dielectric layer 18.

One aspect of the present disclosure recognizes that forming spacer layer 20 in a relatively low temperature environment substantially prevents loss of dopants and deactivation of doped regions within the semiconductor device, for example, in the doped semiconductor gate. Forming first spacer layer 20 in a relatively low temperature environment alleviates some of the problems conventionally associated with dopant depletion in the semiconductor gate.

Conventional methods of forming spacer layers often lead to deactivation of the dopants within the semiconductor gate. Deactivation of the dopants typically results from the relatively high temperature needed to maintain a sufficient deposition rate of the dielectric material. In particular, conventional low pressure chemical vapor deposition (LPCVD) using a dichlorosilane (DCS) gas in the environment, typically requires a temperature of greater than 700° C. to maintain a sufficient deposition rate of the dielectric material. This high temperature imparts sufficiently high activation energy to the dopants, causing the dopants to migrate to the grain boundaries of the dielectric material and/or the edges of the semiconductor gate. This migration of the dopants typically results in dopant loss and deactivation of the semiconductor gate.

Unlike conventional methods of forming spacer layers, formation of first spacer layer 20 occurs in an environment that comprises a relatively low temperature, while maintaining a sufficient deposition rate of the dielectric material. Forming spacer layer 20 in a relatively low temperature substantially minimizes dopant loss and deactivation of the semiconductor gate. This lower temperature substantially prevents the dopants from achieving sufficient activation energy to migrate to the grain boundaries and/or the edges of the semiconductor gate. The environment may comprise any material capable of maintaining a sufficient deposition rate of the dielectric material, for example, bistertiarybutylaminosilane (BTBAS) or hexachlorodisilane (HCD). In some embodiments, formation of first spacer layer occurs in a temperature of 650° C. or less. For example, adequate deposition rates can be achieved in these environments at temperatures of 600° C. or less, 550° C. or less, or 500° C. or less.

Another aspect of the present disclosure recognizes that a sufficient deposition rate can be maintained during the formation of first spacer layer 20 in a relatively low temperature environment. In various embodiments, the rate of deposition can comprise a deposition rate of at least four (4) angstroms per minute. In some cases, deposition rates of seven (7) angstroms per minute or more can be achieved without significantly deactivating dopants in the device.

In this particular embodiment, first spacer layer 20 is formed outwardly from first screen dielectric layer 18. In an alternative embodiment, the thickness of first screen dielectric 18 may be increased to a point that substantially negates the need for the formation of first spacer layer 20 outwardly from first screen dielectric layer. In that embodiment, first screen dielectric layer 18 may comprise an oxide with a thickness of approximately 1-200 angstroms. Formation of first screen dielectric layer 18 may be affected by, for example, growing an oxide, by depositing an oxide, or a combination of growing and depositing an oxide.

FIG. 1D shows a cross sectional view of semiconductor device 10 after formation of drain extension areas 22, after removal of at least a portion of first screen dielectric layer 18, and after removal of at least a portion of first spacer layer 20. Portions of first screen dielectric layer 18 and first spacer layer 20 may be removed, for example, by anisotropically etching first screen dielectric layer 18 and first spacer layer 20. In one particular embodiment, portions of first screen dielectric layer 18 and first spacer layer 20 are removed by performing a plasma etch.

At some point, drain extension areas 22 of semiconductor device 10 can be formed. Drain extension areas 22 of semiconductor device 10 may be formed, for example, by ion implantation or diffusion. Drain extension areas 22 may be formed, for example, prior to removal of portions of first screen dielectric layer 18 and first spacer layer 20. In another embodiment, drain extension areas 22 may be formed after removal of at least a portion of first screen dielectric layer 18 and first spacer layer 20. Removing screen dielectric layer 18 after formation of drain extension areas 22 is advantageous in minimizing damages to semiconductor substrate 12 during formation of drain extension areas 22, for example, by substantially preventing implant channeling in substrate 12.

In this embodiment, portions of first screen dielectric layer 18 disposed outwardly from drain extension areas 20 are completely removed. In an alternative embodiment, portions of first screen dielectric layer 18 remain disposed outwardly from drain extension areas 22 after removal of portions of layers 18 and 20. Leaving at least a portion of first screen dielectric layer 18 disposed outwardly from domain extension areas 22 is advantageous in reducing surface irregularities of substrate 12 formed during the etching process.

FIG. 1E shows a cross sectional view of semiconductor device 10 after formation of a second screen dielectric layer 24 outwardly from substrate 12, a second spacer layer 26 outwardly from second screen dielectric layer 24, and a third screen dielectric layer 28 outwardly from second spacer layer 26. Second screen dielectric layer 24 may comprise, for example, oxide, oxi-nitride, silicon oxide, or nitride. In this particular example, second screen dielectric layer 24 comprises oxide with a thickness of approximately 50-300 angstroms. Forming second screen dielectric layer 24 may be affected, for example, by depositing an oxide outwardly from substrate 12. In one particular embodiment, second screen dielectric layer 24 is formed in a low temperature environment, while maintaining a sufficient deposition rate of the dielectric material.

Second spacer layer 26 may comprise any dielectric material such as, for example, nitride, silicon nitride, oxide, oxi-nitride, or silicon oxide. In some embodiments, second spacer layer 26 may comprise a dielectric material comprising at least seven (7) percent hydrogen and no more than fifty-one (51) percent nitrogen. In other embodiments, second spacer layer 26 may comprise a dielectric material comprising at least fourteen (14) percent hydrogen and no more than forty-two (42) percent nitrogen. In this particular example, second spacer layer 26 comprises nitride with a thickness of approximately 100-500 angstroms. Using nitride as the dielectric material of second spacer layer 26 is particularly advantageous in controlling the etching process. Formation of second spacer layer 26 may be affected, for example, by depositing a dielectric material outwardly from second screen dielectric layer 24. In one particular embodiment, second spacer layer 26 is formed in a low temperature environment, while maintaining a sufficient deposition rate of the dielectric material.

Third screen dielectric layer 28 may comprise, for example, oxide, oxi-nitride, silicon oxide, or nitride. In this particular example, third screen dielectric layer 28 comprises oxide with a thickness of approximately 300 to 1,000 angstroms. Formation of third screen dielectric 28 may be affected by depositing a dielectric material outwardly from second spacer layer 26. In one particular embodiment, third spacer layer 28 is formed in a low temperature environment, while maintaining a sufficient deposition rate of the dielectric material.

Forming screen dielectric layer 24, second spacer layer 26, and third screen dielectric layer 28 in a relatively low temperature environment alleviates the problems conventionally associated with doped drain extension areas during formation of these layers. One aspect of the present disclosure recognizes that forming layers 24, 26, and 28 in a relatively low temperature environment substantially improves semiconductor device conductivity, by substantially minimizing dopant loss and deactivation of the drain extension areas of the semiconductor device and the gate regions.

In this particular embodiment, second spacer layer 26 is formed outwardly from second screen dielectric layer 24. In an alternative embodiment, the thickness of second screen dielectric layer 24 may be increased to a point that substantially negates the need for the formation of second spacer layer 26 outwardly from second screen dielectric layer 24. In that embodiment, second screen dielectric layer 24 may comprise an oxide with a thickness of approximately 50-800 angstroms. Formation of second screen dielectric layer 24 may be affected, for example, by depositing an oxide outwardly from substrate 12.

FIG. 1F shows a cross sectional view of semi-conductor device 10 after formation of drains 30 within substrate 12, and after removal of portions of second screen dielectric layer 24, second spacer layer 26, and third screen dielectric layer 28. Portions of second screen dielectric layer 24, second spacer layer 26, and third screen dielectric layer 28 may be removed, for example, by anisotropically etching layers 24, 26 and 28. In one particular embodiment, portions of layers 24, 26, and 28 may be removed by performing a plasma etch technique.

At some point, drains 30 of semiconductor device 10 may be formed. Drains 30 of semiconductor device 10 may be formed, for example, by deep ion implantation. During ion implantation spacer layer 26 operates to protect drain extension area 22 disposed inwardly from gate 16. In one embodiment, after ion implantation portions of layers 24, 26, and 28 are removed by the anisotropic etch. In an alternative embodiment, a portion or portions of some or all of third screen dielectric layer 28, second spacer layer 26, and/or second screen dielectric layer 24 may be removed prior to formation of drains 30. The total thickness of layers 24, 26, and 28 remaining after removal of a portion or portions of the respective layers depends at least in part on a desired thickness necessary to protect substrate 12 and drain extensions 22 during formation of drains 30.

FIG. 2 is a graph comparing example temperatures and deposition rates of a spacer layer in various environments. Graph 200 represents the deposition rate of a nitride spacer layer in a dichlorosilane (DCS) environment. Graph 225 represents the deposition rate of a nitride spacer layer in the BTBAS environment. Graph 250 represents the deposition rate of a nitride spacer layer in the HCD environment. The horizontal axis in each graph represents the temperature of the environment, while the vertical axis represents the deposition rate of the nitride material.

These graphs illustrate that deposition rates of greater than four (4) angstroms per minute can be achieved in both the BTBAS and HCD environments, where the temperature is approximately 550° C. or more. Graph 200 illustrates that to achieve the same deposition rate in the DCS environment requires a temperature of approximately 700° C. Depositing the nitride spacer layer in the 700° C. DCS environment, typically results in deactivation of the dopants implanted in the semiconductor gate and drain extension areas of the semiconductor device. This deactivation of the dopants normally results in an increase in device resistance and a reduction in device drive current, when compared to a similar device where formation of the nitride spacer layer is in a relatively lower temperature BTBAS or HCD environments.

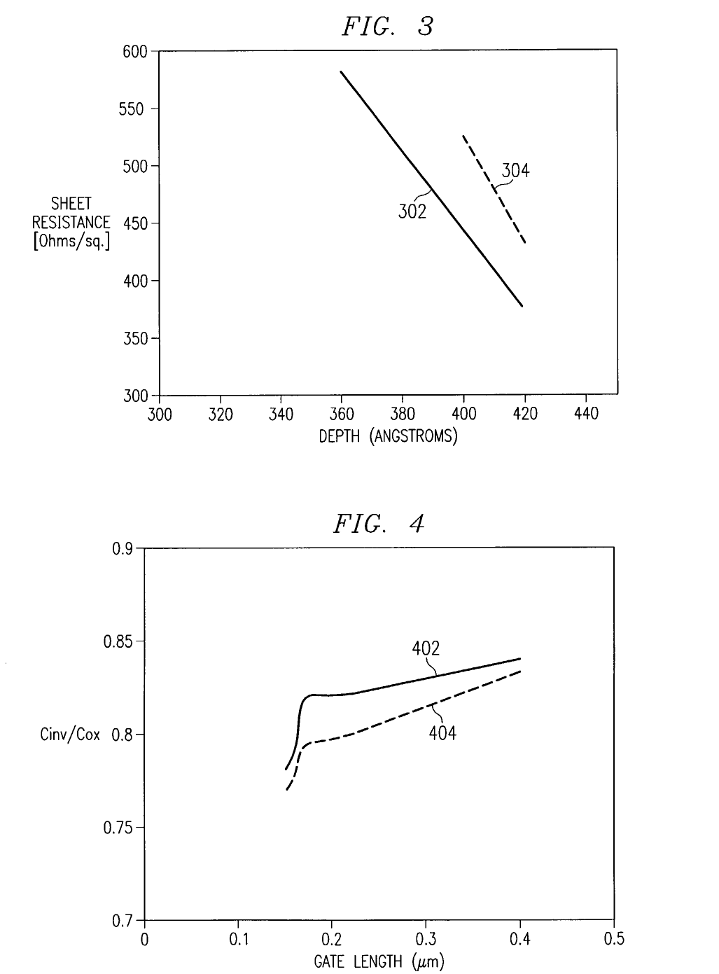

FIG. 3 is a graph comparing the sheet resistance of example semiconductor devices where the spacer layers of each device are formed in either a BTBAS environment or a DCS environment. The structure and function of each spacer layer can be substantially similar to second spacer layer 26 of FIG. 1. In this example, line 302 represents the sheet resistance of a semiconductor device where the formation of the spacer layer occurs in a 550° C. BTBAS environment. Line 304 represents the sheet resistance of a semiconductor device where the formation of the spacer layer occurs in a 740° C. DCS environment. In this example, the thickness of the BTBAS spacer layer comprises approximately 300 angstroms, while the thickness of the DCS spacer layer comprises approximately 800 angstroms. The difference in layer thickness results from the desire to maintain a similar deposition period for the materials, while each spacer layer was deposited at a different deposition rate. Although the BTBAS spacer layer in this example comprises approximately 300 angstroms, similar results can be achieved if the BTBAS spacer layer and the DCS spacer layer were of an approximately equal thickness. The horizontal axis represents the depth of the drain extension area, while the vertical axis represents the sheet resistance of the semiconductor devices.

This graph shows a reduction in the sheet resistance of the semiconductor device for a given drain extension depth when the spacer layer is formed in the lower temperature BTBAS environment. In other words, forming the spacer layer in the relatively low temperature BTBAS environment enables a reduced sheet resistance for a given drain extension depth. For example, where each device comprises a drain extension depth of approximately 418 angstroms, sheet resistance is reduced approximately 50 ohms when the spacer layer is formed in the BTBAS environment. The reduction in sheet resistance of the semiconductor device, where the nitride spacer is formed in the BTBAS environment, depends at least in part on the ability of the BTBAS environment to minimize dopant loss and deactivation, while maintaining a sufficient rate of deposition. Similar improvements can be realized over DCS by forming the spacer layer in a HCD environment.

FIG. 4 is a graph comparing the substrate to gate capacitance of example semiconductor devices where each of the spacer layers are formed in either a BTBAS environment or a DCS environment. The structure and function of each spacer layer can be substantially similar to first spacer layer 20 of FIG. 1. In this example, line 402 represent a capacitance of a semiconductor device where the formation of the spacer layer occurs in a 550° C. BTBAS environment. Line 404 represents the capacitance of a semiconductor device where the formation of the spacer layer occurs in a 740° C. DCS environment. In this example, the thickness of the pad oxide layer of each semiconductor device is substantially similar. The horizontal axis represents the length of the gate, while the vertical axis represents a metric for substrate to gate capacitance. This metric compares the inversion capacitance (Cᵢₙᵥ) of the gate oxide to the accumulation capacitance (Cₒₓ) of the gate oxide. The term “inversion capacitance” refers to the capacitance of the semiconductor device while the semiconductor device is under inversion. The term “accumulation capacitance” refers to the capacitance of the semiconductor device when the semiconductor device is in accumulation.

This graph shows an increase in the inversion gate capacitance of the semiconductor device for a given gate length when the spacer layer is formed in the BTBAS environment. In other words, forming the spacer layer in a lower temperature BTBAS environment enables an improvement in inversion capacitance for similar gate lengths. For example, where each device comprises a gate length of approximately 230 angstroms, device inversion capacitance to accumulation capacitance ratio increases by approximately 0.25 when the spacer layer is formed in the BTBAS environment. This ratio tends to improve upon a reduction in the amount of dopants deactivated within the semiconductor gate. Reducing the amount of dopant loss and deactivation in the semiconductor gate typically increases the inversion capacitance, but has minimal impact on the accumulation capacitance. In other words, the inversion capacitance is a measure for indicating how many dopants remain activated within the semiconductor gate. Consequently, the semiconductor device where the spacer layer is formed in the BTBAS environment shows a higher inversion capacitance for the same gate length which results in a higher inversion charge and a higher drive current, when compared to the DCS formed spacer layer semiconductor device. Similar improvements can be realized over DCS by forming the spacer layer in a HCD environment.

Although the present invention has been described in several embodiments, a myriad of changes, variations, alterations, transformations, and modifications may be suggested to one skilled in the art, and it is intended that the present invention encompass such changes, variations, alterations, transformations, and modifications as falling within the spirit and the scope of the appended claims.

What is claimed is:

1. A method of forming a semiconductor device, comprising:
doping at least one region of an at least partially formed semiconductor device; and
depositing at least one spacer layer outwardly from the at least one region of the at least partially formed semiconductor device;
wherein the at least one deposited spacer layer is formed in an environment that substantially minimizes dopant loss and deactivation in the at least one region of the at least partially formed semiconductor device.

2. The method of claim 1, wherein the at least one region of the at least partially formed semiconductor device comprises a drain extension area.

3. The method of claim 1, wherein the at least one region of the at least partially formed semiconductor device comprises a semiconductor gate.

4. The method of claim 1, wherein the at least one deposited spacer layer comprises a dielectric material selected from a group consisting of nitride, oxide, oxi-nitride, and silicon oxide.

5. The method of claim 1, wherein the at least one deposited spacer layer comprises a dielectric material comprising at least seven (7) percent hydrogen and no more than fifty-one (51) percent nitrogen.

6. The method of claim 1, wherein the at least one deposited spacer layer comprises a dielectric material comprising at least fourteen (14) percent hydrogen and no more than forty-two (42) percent nitrogen.

7. The method of claim 1, wherein the environment comprises a temperature of approximately 500 to 650 degrees Celsius.

8. The method of claim 1, wherein the environment comprises a material selected from a group consisting of bistertiarybutylaminosilane (BTBAS) and hexachlorodisilane (HCD).

9. The method of claim 1, wherein the semiconductor device comprises a reduction in sheet resistance of at least 50 Ohms less than would result if the semiconductor device were formed in an environment comprising dichlorosilate (DCS).

10. The method of claim 1, wherein the level of dopant loss and deactivation is lower than a level of dopant loss and deactivation that would result if the semiconductor device were formed in an environment comprising dichlorosilate (DCS).

11. The method of claim 1, wherein an average deposition rate for the at least one spacer layer comprises a deposition rate of at least four (4) Angstroms per minute.

12. The method of claim 1, wherein the semiconductor device comprises a transistor.

13. The method of claim 1, further comprising providing additional dopant to the semiconductor device after formation of the at least one deposited spacer layer.

14. A method of forming a semiconductor device, comprising:
doping at least one region of an at least partially formed semiconductor device; and
depositing at least one spacer layer outwardly from the at least one region of the at least partially formed semiconductor device, wherein the at least one spacer layer is deposited at a rate of at least four (4) Angstroms per minute;
wherein the at least one spacer layer comprises a dielectric material comprising at least seven (7) percent hydrogen and no more than fifty-one (51) percent nitrogen after depositing;
wherein the at least one spacer layer is deposited in an environment comprising a temperature of 500 to 650 degrees Celsius.

15. The method of claim 14, wherein the temperature of the environment reduces dopant loss and deactivation in at least one region of the semiconductor device.

16. The method of claim 14, wherein the at least one deposited spacer layer comprises a dielectric material comprising at least fourteen (14) percent hydrogen and no more than forty-two (42) percent nitrogen.

17. The method of claim 14, wherein the environment comprises a material selected from a group consisting of bistertiarybutylaminosilane (BTBAS) and hexachlorodisilane (HCD).

18. A transistor formed using a method, comprising:
doping at least one region of an at least partially formed transistor; and
depositing at least one spacer layer outwardly from the at least one region of the at least partially formed transistor;
wherein the at least one deposited spacer layer is formed in an environment that substantially minimizes dopant loss and deactivation in the at least one region of the at least partially formed transistor, while maintaining an average deposition rate for the at least one deposited spacer layer of at least four (4) Angstroms per minute.

19. The transistor of claim 18, wherein the environment comprises a temperature of approximately 500 to 650 degrees Celsius.

20. The transistor of claim 18, wherein the environment comprises a gas selected from a group consisting of bistertiarybutylaminosilane (BTBAS) and hexachlorodisilane (HCD).
